(19) United States
(12) Patent Application Publication
(10) Pub. No.: US 2010/0051958 A1
(43) Pub. Date: Mar. 4, 2010

(54) DISPLAY DEVICE AND MANUFACTURING METHOD THEREOF

(75) Inventors: Takeshi Izumida, Mobara (JP); Kenta Kajiyama, Mobara (JP); Hajime Akimoto, Kokubunji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/553,147

(22) Filed: Sep. 3, 2009

(30) Foreign Application Priority Data
Sep. 4, 2008 (JP) 2008-226645

(51) Int. Cl. H01L 33/00; H01L 21/28

(52) U.S. Cl. 257/72; 438/29; 257/E33.053; 257/E21.158

(57) ABSTRACT

A display device includes an insulation substrate on which TFT elements, first electrodes, light emitting layers and a second electrode are stacked in this order. Auxiliary lines are arranged between the insulation substrate and the second electrodes, and an insulation layer is interposed between the auxiliary lines and the second electrode. The auxiliary lines and the second electrode are connected with each other via contact holes formed in the insulation layer. Due to such a constitution, it is possible to enhance image quality of an organic EL display device.

### CROSS-REFERENCE TO RELATED APPLICATION

The present application claims priority from Japanese application JP 2008-226645 filed on Sep. 4, 2008, the content of which is hereby incorporated by reference into this application.

### BACKGROUND OF THE INVENTION

1. Field of the Invention

The present invention relates to a display device, and more particularly to a technique which is effectively applicable to a self-luminous display device in which a light-emitting layer is interposed between a first electrode and a second electrode.

2. Description of the Related Art

Conventionally, as one of the self-luminous display devices, there has been known a display device which uses an organic EL (electroluminescence) material (hereinafter, referred to as an organic EL display device).

In the organic EL display device, pixels each of which includes a TFT element, a first electrode which is connected to the TFT element, a second electrode which faces the first electrode in an opposed manner, and a light emitting layer (organic EL layer) which is interposed between the first electrode and the second electrode are arranged in a matrix array, and light emitting intensity of each organic EL layer (brightness of each pixel) is controlled based on a quantity of electric current which flows between the first electrode and the second electrode thus displaying a video or an image. In such a constitution, the second electrode is a common electrode used in common by a plurality of pixels.

In a display panel which is used for the organic EL display device, the TFT element, the first electrode, the light emitting layer and the second electrode are stacked on a surface of an insulation substrate in this order, for example. Here, the second electrode is formed of a transparent conductive material such as IZO or ITO, for example. Light emitted from the light emitting layer is radiated to the outside of the display panel after passing the second electrode. The organic EL display device having such structure is referred to as a top-emission-type organic EL display device.

In the top-emission-type organic EL display device, the second electrode is usually formed of a sheet of transparent conductive film which is formed over the whole surface of a display region. Accordingly, when the display region becomes large, there arises a drawback that display irregularities or the like occur due to a voltage drop of the second electrode, for example.

As a method for preventing such occurrence of voltage drop of the second electrode, for example, there has been proposed a method in which auxiliary lines made of metal having low resistance such as aluminum (Al) are arranged in a stripe shape in gaps each defined between the respective pixels, and the second electrode and the auxiliary lines are connected to each other.

In the manufacturing method of the display panel of the conventional organic EL display device, in general, the auxiliary lines are formed by a vapor deposition method using a mask (for example, see JP-A-2007-265756 (patent document 1) and JP-A-2007-073323 (patent document 2)).

### SUMMARY OF THE INVENTION

Informing the auxiliary lines by a vapor deposition method using a mask, for example, auxiliary lines having a predetermined pattern are directly formed on a surface of an insulation layer. Accordingly, the formation of the auxiliary lines by a vapor deposition method can be carried out efficiently compared to a case where a conductive film is formed and, thereafter, the conductive film is etched so as to form auxiliary lines.

However, in forming the auxiliary lines by a vapor deposition method using a mask, for example, there exists a possibility that due to the misalignment or distortion (deformation) of a mask, the formation position of the auxiliary lines is displaced or a planar size of the auxiliary lines becomes larger than a size of the auxiliary lines at the time of designing. Accordingly, in forming the auxiliary lines by a vapor deposition method using a mask, it is necessary to ensure a large margin around the auxiliary line for preventing a defective operation attributed to contact or interference of the auxiliary line with other conductive material thus making the increase of a light emitting region of each pixel difficult. As a result, the conventional organic EL display device having the auxiliary lines have drawbacks that it is difficult to enhance the brightness of each pixel, it is difficult to enhance light emitting efficiency with respect to electricity, it is difficult to enhance image quality, and it is difficult to lower power consumption, for example.

Further, in the method for manufacturing an organic EL display device described in patent document 1, for example, contact holes (opening portions 110a) which connect auxiliary lines (cathode lines 60) with a second electrode (cathode 50) are formed in an insulation layer (organic film 110) which is formed on the auxiliary lines by ashing. Accordingly, this manufacturing method has a drawback that a manufacturing cost of the organic EL display device is pushed up.

It is an object of the present invention to provide a technique which can enhance image quality of an organic EL display device.

It is another object of the present invention to provide a technique which can reduce power consumption of an organic EL display device.

It is still another object of the present invention to provide a technique which can reduce a manufacturing cost of an organic EL display device.

The above-mentioned and other objects of the present invention and novel technical features of the present invention will become apparent from the description of this specification and attached drawings.

In a display device of the present invention, pixels each of which includes a TFT element, a first electrode which is connected to the TFT element, a second electrode which faces the first electrode in an opposed manner, and a light emitting layer which is interposed between the first electrode and the second electrode are arranged on an insulation substrate in a matrix array. The second electrode is formed of a transparent conductive material used in common by a plurality of pixels and is connected to auxiliary lines which are formed on the insulation substrate. The TFT element, the first electrode, the light emitting layer and the second electrode are stacked on the insulation substrate in this order. The auxiliary lines are arranged between the insulation substrate and the second electrode and a bank layer which is formed of an insulation material is interposed between the auxiliary lines and the second electrode. The auxiliary line and the second electrode are connected with each other via a contact hole formed in the bank layer which is interposed between the auxiliary lines and the second electrode.

### BRIEF DESCRIPTION OF THE DRAWINGS

FIG. 1A is a schematic plan view showing one example of the constitution of pixels of an organic EL display device according to one embodiment of the present invention;

FIG. 1B is a schematic cross-sectional view showing one example of the cross-sectional constitution taken along a line A-A′ in FIG. 1A;

FIG. 1C is a schematic circuit diagram showing one example of the circuit constitution of one pixel of the organic EL display device;

FIG. 1D is a schematic view showing one example of the manner of an operation of the organic EL display device having the constitution shown in FIG. 1C;

FIG. 2A is a schematic cross-sectional view showing one example of the cross-sectional constitution of a TFT substrate immediately after a TFT element is formed;

FIG. 2B is a schematic cross-sectional view showing one example of the cross-sectional constitution of the TFT substrate immediately after a fourth insulation layer is formed;

FIG. 2C is a schematic cross-sectional view showing one example of the cross-sectional constitution of the TFT substrate immediately after a reflection film and an auxiliary line are formed;

FIG. 2D is a schematic cross-sectional view showing one example of the cross-sectional constitution of the TFT substrate immediately after a first electrode is formed;

FIG. 2E is a schematic cross-sectional view showing one example of the cross-sectional constitution of the TFT substrate immediately after a bank layer is formed; and

FIG. 2F is a schematic cross-sectional view showing one example of the cross-sectional constitution of the TFT substrate immediately after an organic EL layer is formed.

### DESCRIPTION OF THE PREFERRED EMBODIMENTS

To briefly explain the summery of typical inventions among inventions disclosed in this specification, they are as follows.

(1) In a display device in which pixels each of which includes a TFT element, a first electrode which is connected to the TFT element, a second electrode which faces the first electrode in an opposed manner, and a light emitting layer which is interposed between the first electrode and the second electrode are arranged on an insulation substrate in a matrix array, and the second electrode is formed of a transparent conductive material used in common by a plurality of pixels and is connected to auxiliary lines which are formed on the insulation substrate, the TFT element, the first electrode, the light emitting layer and the second electrode are stacked on the insulation substrate in this order, the auxiliary lines are arranged between the insulation substrate and the second electrode and a bank layer which is formed of an insulation material is interposed between the auxiliary lines and the second electrode, and the auxiliary line and the second electrode are connected with each other via a contact hole formed in the bank layer which is interposed between the auxiliary lines and the second electrode.

(2) In the display device having the constitution (1), the first electrodes and the auxiliary lines are formed on the same surface of one insulation layer formed on the insulation substrate.

(3) In the display device having the constitution (2), a reflection film is arranged between the first electrode and one insulation layer.

(4) In the display device having the constitution (1), the bank layer is arranged on the first electrodes, the bank layer includes opening portions through which a portion of the first electrode is exposed, and the light emitting layer is filled in the opening portion formed in the bank layer.

(5) In the display device having the constitution (4), the pixels are arranged in a matrix array such that either one of the relationship between two pixels arranged adjacent to each other in the row direction with respect to a planar shape of the opening potion formed in the bank layer and the relationship between two pixels arranged adjacent to each other in the columnar direction with respect to a planar shape of the opening portion formed in the bank layer adopts a line symmetry using a boundary between two pixels as an axis of symmetry but does not adopt a translational symmetry.

(6) In a manufacturing method of a display device which forms pixels each of which includes a TFT element, a first electrode which is connected to the TFT element, a second electrode which faces the first electrode in an opposed manner and a light emitting layer which is interposed between the first electrode and the second electrode, and auxiliary lines which are connected to the second electrode on an insulation substrate, the manufacturing method includes the steps of: forming the TFT elements on the insulation substrate; forming the first electrodes and the auxiliary lines; forming an insulation layer which has first opening portions through which a portion of the first electrode is exposed and second opening portions through which a portion of the auxiliary line is exposed; filling the light emitting layer in the first opening portion; and forming the second electrode which is connected to the light emitting layers via the first opening portions and is connected to the auxiliary lines via the second opening portions, and the first electrodes and the auxiliary lines are formed by etching a conductive film in the step of forming the first electrodes and the auxiliary lines.

(7) In the manufacturing method of a display device having the constitution (6), the step for forming the first electrodes and the auxiliary lines includes the steps of: forming reflection films and the auxiliary lines by etching a metal film; and forming the first electrodes by etching a transparent conductive film.

(8) In the manufacturing method of a display device having the constitution (6), in the step for forming the first electrodes and the auxiliary lines, a metal film and a transparent conductive film are formed continuously and, thereafter, the first electrodes, the auxiliary lines and the reflection films are formed by etching the transparent conductive film and the metal film.

(9) In the manufacturing method of a display device having the constitution (6), in the step for forming the first electrodes and the auxiliary lines, the first electrodes and the auxiliary lines are formed by etching a metal film.

According to the present invention, it is possible to easily increase a light emitting region of each pixel compared to a conventional organic EL display device having auxiliary lines. Accordingly, the display device of the present invention and the manufacturing method of the display device of the present invention can enhance image quality of the organic EL display device having the auxiliary lines. Further, the display device of the present invention and the manufacturing method of the display device of the present invention can reduce the power consumption of the organic EL display device having the auxiliary lines.

Still further, the manufacturing method of the display device of the present invention can reduce a manufacturing cost of the organic EL display device having the auxiliary lines.

Hereinafter, the present invention is explained in detail in conjunction with drawings and an embodiment. Here, in all drawings for explaining the embodiment, parts having identical functions are given same numerals and their repeated explanation is omitted.

### Embodiment 1

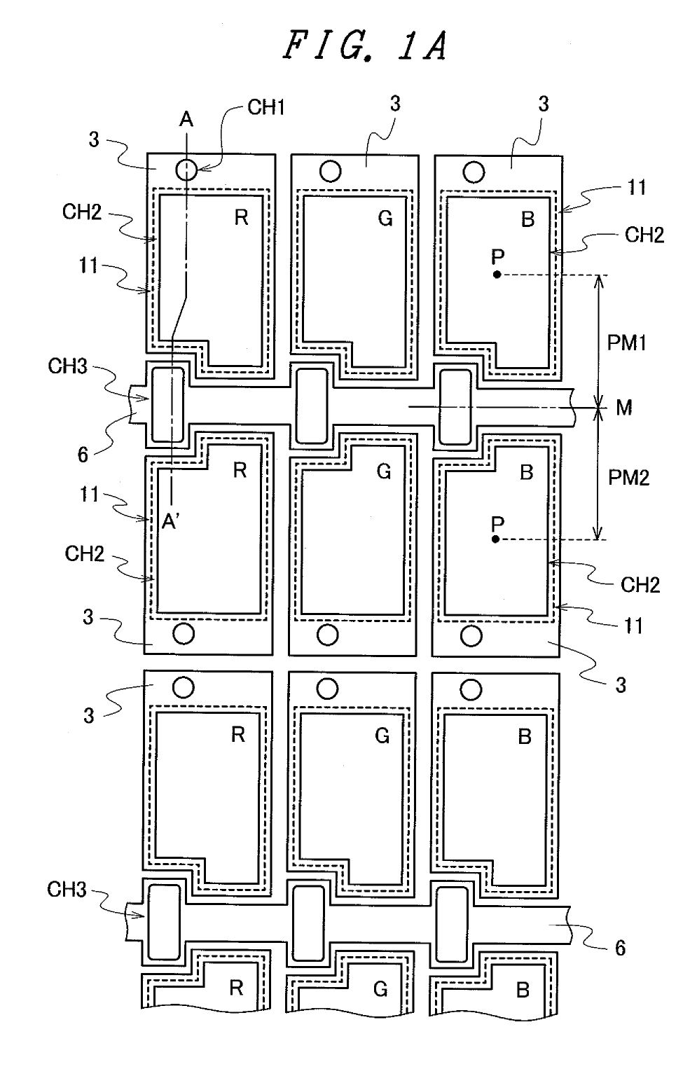

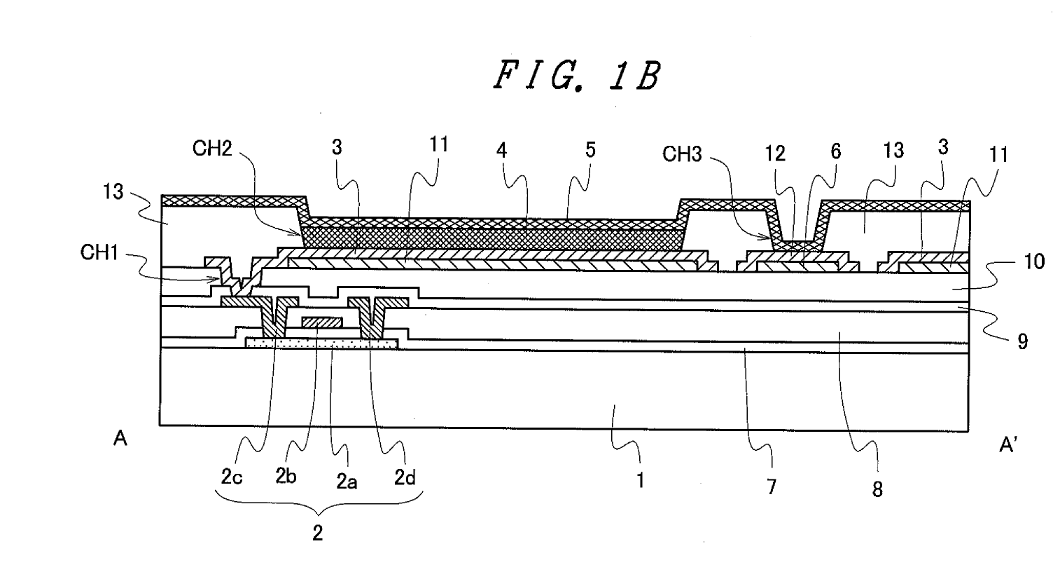

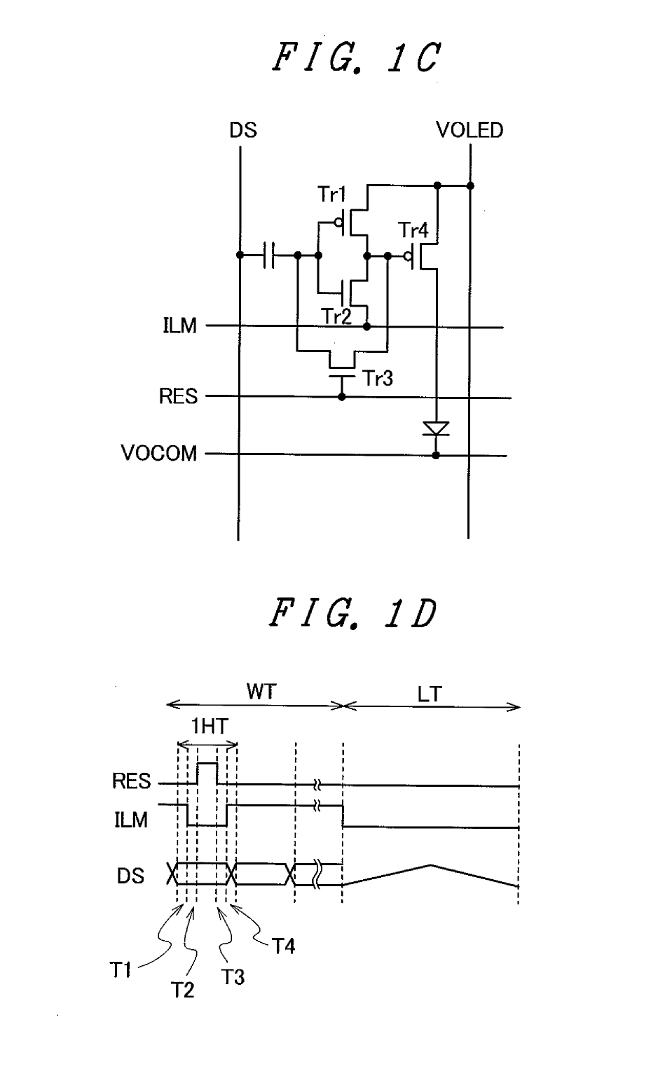

FIG. 1A to FIG. 1D are schematic views showing the schematic constitution of an organic EL display device of one embodiment according to the present invention. FIG. 1A is a schematic plan view showing one example of the constitution of a pixel of the organic EL display device according to one embodiment of the present invention. FIG. 1B is a schematic cross-sectional view showing one example of the cross-sectional constitution taken along a line A-A′ in FIG. 1A. FIG. 1C is a schematic circuit diagram showing one example of the circuit constitution of one pixel of the organic EL display device. FIG. 1D is a schematic view showing one example of the manner of operation of the organic EL display device having the constitution shown in FIG. 1C.

A display panel of the organic EL display device is usually constituted of a pair of substrates which are arranged to face each other in an opposed manner with a preset gap therebetween. Here, on one substrate out of the pair of substrates, pixels each of which includes a TFT element, a first electrode, a light emitting layer and a second electrode are arranged in a matrix array, for example. The present invention relates to the substrate on which the above-mentioned pixels are arranged in a matrix array (hereinafter, referred to as a TFT substrate) in the organic EL display device.

The TFT substrate of the organic EL display device of this embodiment is, for example, as shown in FIG. 1A and FIG. 1B, constituted such that the pixels each of which includes a TFT element 2, a first electrode 3, a light emitting layer 4 and a second electrode 5 are arranged on a surface of an insulation substrate 1 in a matrix array. Further, auxiliary lines 6 which are connected to the second electrode 5 are formed on the surface of the insulation substrate 1. The auxiliary lines 6 are metal-made lines for suppressing a voltage drop of the second electrode 5.

Here, on the surface of the insulation substrate 1, semiconductor layers 2a of the TFT elements 2 and a first insulation layer 7 which covers the semiconductor layers 2a are formed. The semiconductor layers 2a are made of poly-crystalline silicon, for example. The first insulation layer 7 functions as a gate insulation film for the TFT elements 2 and is formed of a silicon oxide film (SiO₂ film), for example.

On the first insulation layer 7, gate electrodes 2b of the TFT elements 2 and a second insulation film 8 which covers the gate electrodes 2b are formed. The gate electrodes 2b are made of metal such as aluminum, for example. The second insulation layer 8 is formed of a silicon oxide film or the like, for example.

Source electrodes 2c and drain electrodes 2d of the TFT element 2 and a third insulation layer 9 which covers the source electrodes 2c and the drain electrodes 2d are formed on the second insulation film 8, and a fourth insulation layer 10 is formed on the third insulation layer 9. The source electrodes 2c and the drain electrodes 2d are made of metal such as aluminum, for example. Here, the source electrode 2c is connected to a source diffusion region of the semiconductor later 2a via a first contact hole (not shown in the drawing) which penetrates the first insulation layer 7 and the second insulation layer 8. The drain electrode 2d is connected to a drain diffusion region of the semiconductor layer 2a via a second contact hole (not shown in the drawing) which penetrates the first insulation layer 7 and the second insulation layer 8.

Further, the third insulation layer 9 is formed of a silicon nitride film (SiN film), for example. The fourth insulation layer 10 is made of an organic resin material such as acrylic or polyimide, for example.

On the fourth insulation layer 10, the reflection films 11, the auxiliary lines 6, the first electrodes 3, conductive films 12 which cover the auxiliary lines 6, and a fifth insulation layer 13 (bank layer) which covers the first electrodes 3 and the auxiliary lines 6 are formed. The reflection films 11 and the auxiliary lines 6 are made of metal such as aluminum, for example. The first electrodes 3 and the conductive films 12 which cover the auxiliary lines 6 are formed of a transparent conductive material such ITO or IZO. Here, the first electrode 3 is connected to the source electrode 2c of the TFT element 2 via a third contact hole (not shown in the drawing) which is formed in the third insulation layer 9 and a fourth contact hole CH1 which is formed in the fourth insulation layer 10.

The bank layer 13 is formed of an organic resin material such as acrylic and polyimide, for example. Here, a first opening portion CH2 through which a predetermined region of the first electrode 3 is exposed and a second opening portion CH3 through which a predetermined region of the auxiliary line 6 is exposed are formed in the bank layer 13. Here, for example, the light emitting layer 4 which is made of an organic EL material is formed in the first opening portion CH2 formed in the bank layer 13.

The second electrode 5 is formed on the bank layer 13. The second electrode 5 is made of a transparent conductive material such as IZO or ITO, for example. Here, the second electrode 5 is connected to the light emitting layers 4 via the first opening portions CH2 formed in the bank layer 13 and, at the same time, is connected to the auxiliary lines 6 (conductive layers 12) via the second opening portions CH3. The second electrode 5 is used in common by a plurality of pixels and, for example, is formed of one conductive film which is formed on the whole surface of the display region. The second electrode 5 which constitutes one conductive film is connected to the auxiliary lines 6 at a plurality of positions within the display region.

The circuit constitution of one pixel in the display panel of the organic EL display device includes, as shown in FIG. 1C, two N-channel MOS transistors, two P-channel MOS transistors, a diode, and a capacitive element, for example. The display panel of the organic EL display device includes, in addition to the above-mentioned components, power source lines VOLED, common lines VOCOM, light emitting control signal lines ILM, reset control signal lines RES, and data signal lines DS and the like, for example. The above-mentioned MOS transistors, lines and the like are formed on the TFT substrate and are usually formed on the same layer as the TFT element 2 shown in FIG. 1B. That is, the above-mentioned MOS transistors and lines are formed between the insulation substrate 1 and the third insulation layer 9. Here, planar shapes or arrangement positions of the MOS transistors and the like arranged between the insulation substrate 1 and the third insulation layer 9 may be set by directly adopting planar shapes and arrangement positions of a well-known organic EL display device or by modifying the planar shapes and arrangement positions of a well-known organic EL display device. Accordingly, in this specification, the detailed explanation of the constitution of the MOS transistor and the like arranged between the insulation substrate 1 and the third insulation layer 9 is omitted.

A period (1 frame period) during which 1 frame of an image is displayed in the organic EL display device is divided. That is, the period consists of a writing period WT during which data voltages are sequentially stored in the capacitive elements of the respective pixels which are arranged in a matrix array for every one row, and a light emitting period LT during which the pixels are allowed to emit light only during a period corresponding to the data voltage stored in the capacitive element in the writing period WT. As one example of the manner of operation of the organic EL display device having the circuit constitution as shown in FIG. 1C, waveforms of voltages which are inputted to various signal lines during 1 frame period are shown in FIG. 1D.

A writing operation sequence on a certain pixel row during the writing period WT is explained. First of all, a desired data voltage is inputted to the data signal line DS. Next, the light emitting control signal line ILM assumes a LOW level at timing T1. Thereafter, the reset control signal line RES assumes a HIGH level at timing T2 so that a third transistor Tr3 is turned ON. Here, the input and the output of an inverter which is constituted of a first transistor Tr1 and a second transistor Tr2 are short-circuited, and a differential between the data voltage and an output voltage of the inverter is stored in the capacitive element of each pixel. Next, the reset control signal line RES assumes a LOW level at timing T3, and the light emitting control signal line ILM assumes a HIGH level at timing T4. As a voltage value at a HIGH level, a potential equal to a potential of the power source line VOLED is inputted. Therefore, a potential of an output part of the inverter is held by the power source line VOLED, and a fourth transistor Tr4 is turned OFF. Accordingly, there is no possibility that a voltage is applied to the organic EL light emitting element during the writing periods of other pixel rows. Thereafter, the substantially equal sequence is sequentially applied to other pixel rows so that the data voltages are stored in the capacitive elements of the pixels on other pixel rows.

Further, in the light emitting period LT, the light emitting control signal lines ILM in all pixels assume a LOW level, and a triangular wave voltage is inputted to the data signal lines DS. Here, the data voltage stored in each pixel and the triangular wave voltage are compared to each other and, the transistor Tr4 is turned on only when the difference between the triangular wave voltage and the data voltage becomes lower than a threshold voltage of the inverter. That is, in the organic EL display device having such a constitution, the light emitting period is modulated depending on the data voltage and hence, each pixel can emit light with desired brightness.

Further, the organic EL display device of this embodiment is a display device which is compatible with an RGB-method color display, wherein one pixel on the TFT substrate performs any one of a red (R) grayscale display, a green (G) grayscale display and a blue (B) grayscale display. In FIG. 1A, symbols “R”, “G” and “B” which are respectively indicated at right upper portions of the first opening portions CH2 of the respective pixels indicate colors of grayscale displays performed by the respective pixels. Here, a color of a video or an image for 1 dot is expressed by the combination of three, four or more pixels which are continuously arranged in the lateral direction.

Further, in the TFT substrate of this embodiment, one auxiliary line 6 is allocated to two pixels which are arranged adjacent to each other in the longitudinal direction. Here, the respective auxiliary lines 6 extend in the lateral direction.

Here, the auxiliary line 6 increases a width thereof only at portions thereof where the second opening portion CH3 is formed and decreases the width thereof at other portions thereof. The shape of the first opening portion CH2 is not a simple rectangular shape but is a planar shape where a portion of a side of a rectangular shape along the auxiliary line projects in a rectangular shape.

Still further, with respect to two pixels which are arranged adjacent to each other with the auxiliary line 6 sandwich therebetween, the planar-shaped first opening portions CH1 formed in these pixels respectively are arranged in line symmetry using a boundary M (center line of the auxiliary line 6) of two pixels as an axis of symmetry, but are not arranged in translational symmetry. Due to such arrangement, with respect to two pixels which are arranged adjacent to each other with the auxiliary line 6 sandwich therebetween, a distance PM1 between the center of gravity P of the first opening portion CH2 (the center of gravity of the light emitting region) of one pixel and the boundary M (the center line of the auxiliary line 6) of two pixels, and a distance PM2 between the center of gravity P of the first opening portion CH2 of the other pixel and the boundary M are set equal.

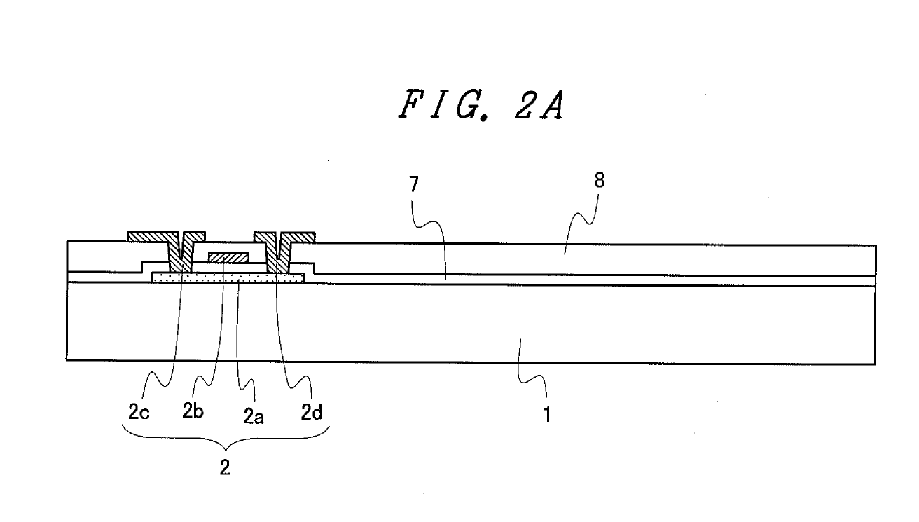

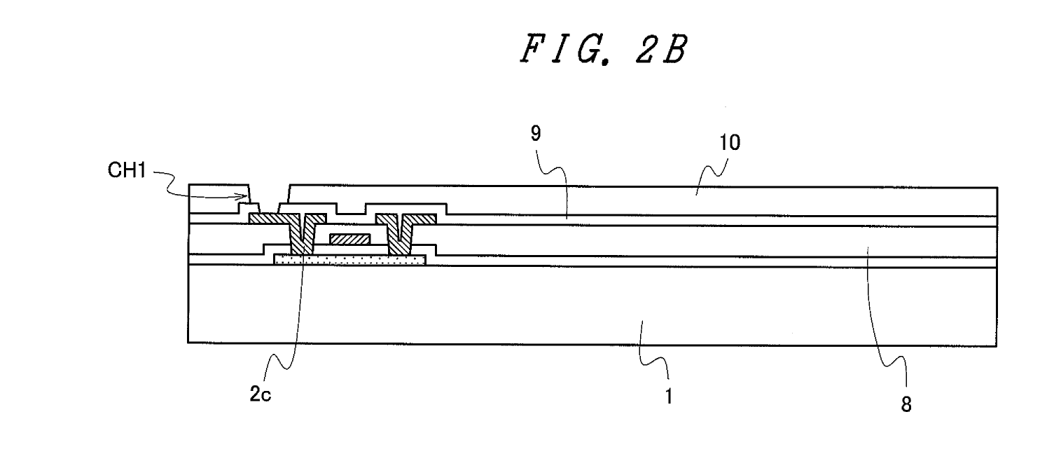

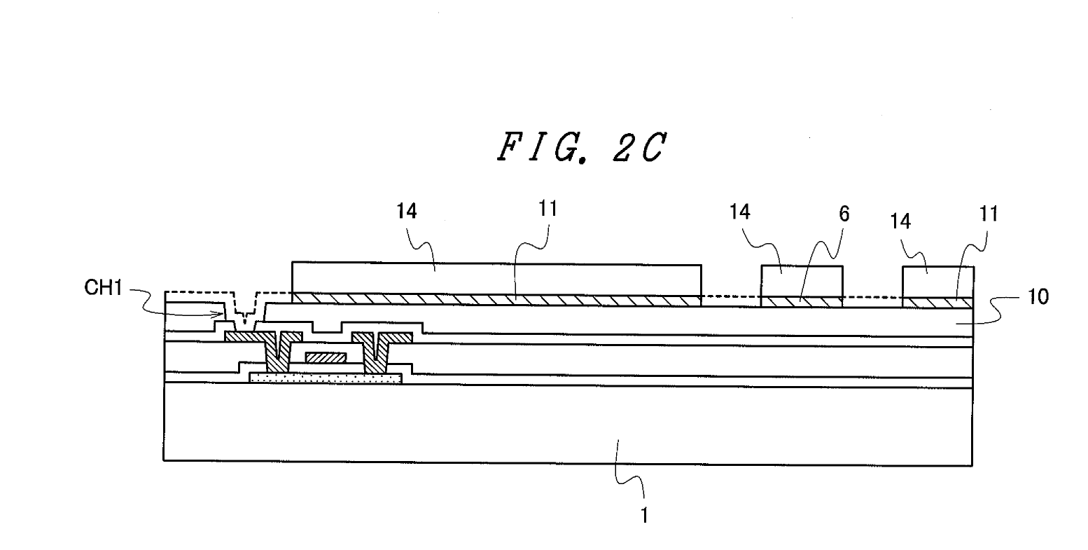

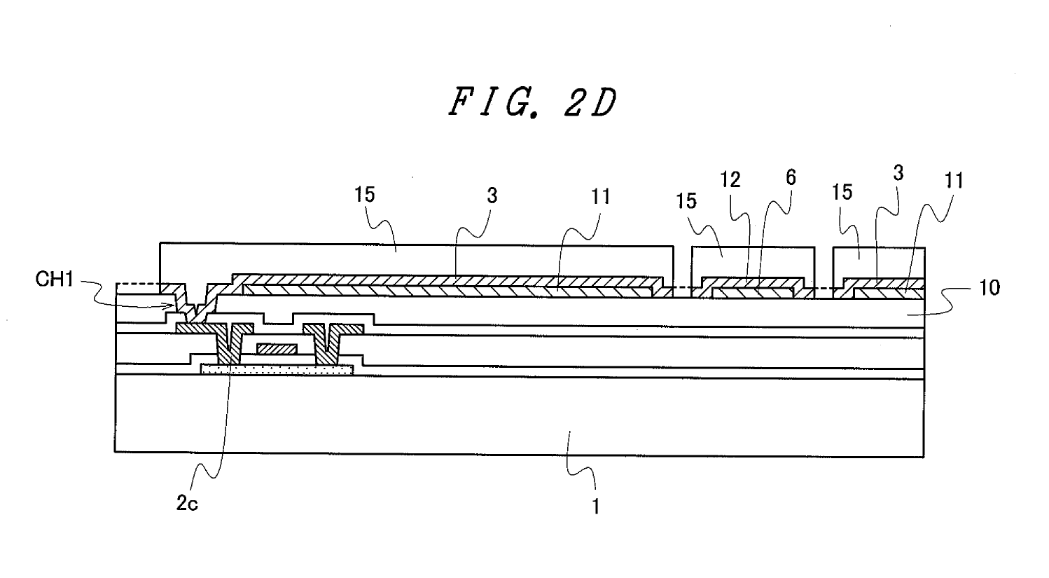

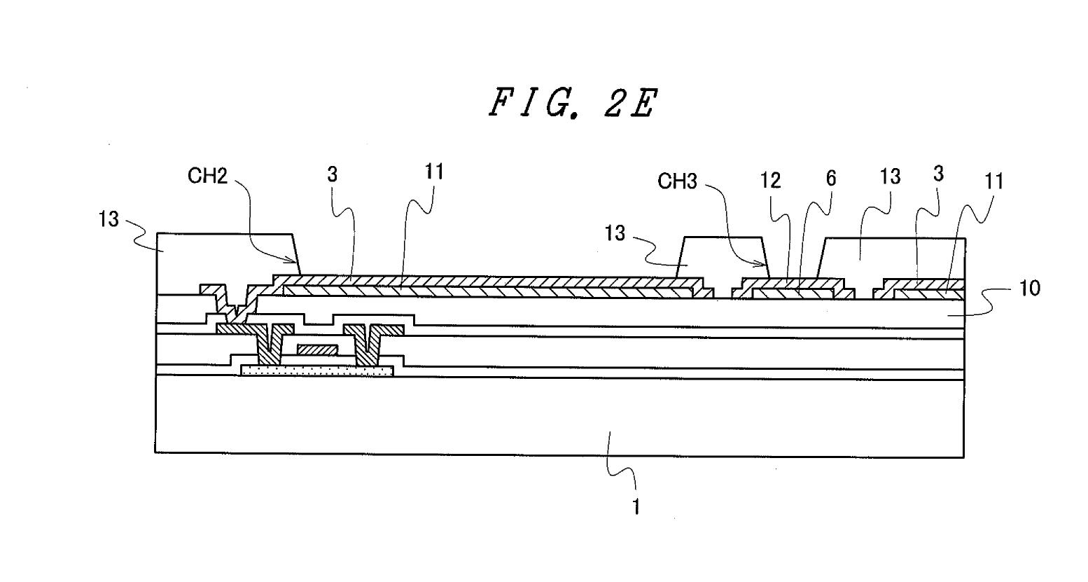

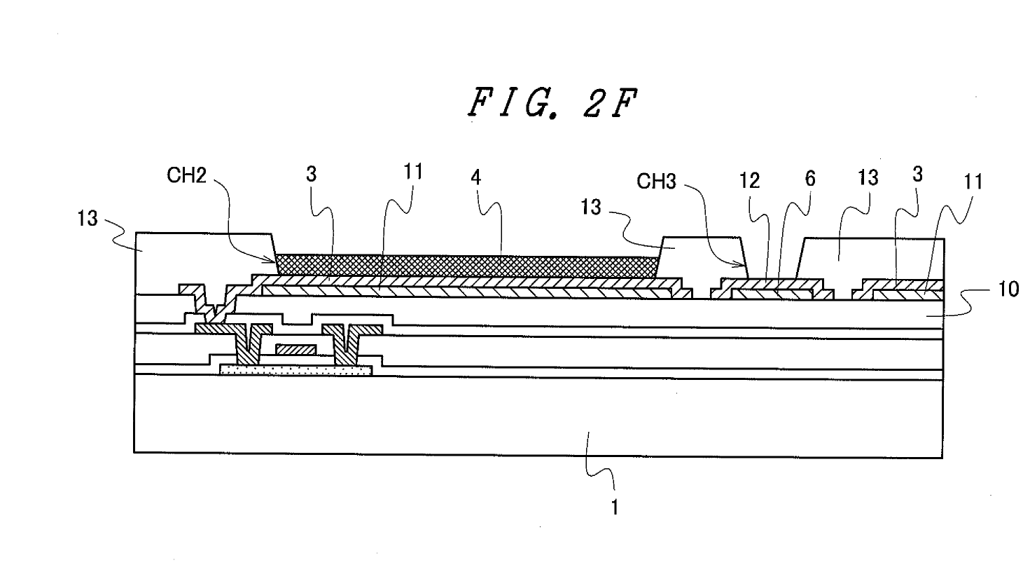

FIG. 2A to FIG. 2F are schematic views showing one example of a manufacturing method of the TFT substrate which is used in the organic EL display device of this embodiment. FIG. 2A is a schematic cross-sectional view showing one example of the cross-sectional constitution of the TFT substrate immediately after the TFT element is formed. FIG. 2B is a schematic cross-sectional view showing one example of the cross-sectional constitution of the TFT substrate immediately after the fourth insulation layer is formed. FIG. 2C is a schematic cross-sectional view showing one example of the cross-sectional constitution of the TFT substrate immediately after the reflection films and the auxiliary lines are formed. FIG. 2D is a schematic cross-sectional view showing one example of the cross-sectional constitution of the TFT substrate immediately after the first electrodes are formed. FIG. 2E is a schematic cross-sectional view showing one example of the cross-sectional constitution of the TFT substrate immediately after the bank layer is formed. FIG. 2F is a schematic cross-sectional view showing one example of the cross-sectional constitution of the TFT substrate immediately after the organic EL layers are formed. Here, FIG. 2A to FIG. 2F show one example of the cross-sectional constitution of the TFT substrate taken along a line A-A′ in FIG. 1A immediately after the respective steps are finished.

In forming the TFT substrate which is used in the organic EL display device of this embodiment, first of all, as shown in FIG. 2A, the MOS transistors such as the TFT elements 2, the diodes and the various kinds of lines are formed on the surface of the insulation substrate 1. With respect to these steps for forming the TFT substrate described above, conventional corresponding steps for forming a display panel may be used in the same manner and hence, the detailed explanation of steps of forming the semiconductor layers 2a, the first insulation layer 7, the gate electrodes 2b, the second insulation layer 8, the source electrodes 2c, the drain electrodes 2d and the like is omitted here. Further, although a surface of the second insulation layer 8 is flattened in this embodiment, the formation of the second insulation layer 8 is not limited to such a constitution. For example, the second insulation layer may be formed with an uneven surface such that the second insulation layer 8 has the substantially the same thickness at respective positions.

Next, as shown in FIG. 2B, the third insulation layer and the fourth insulation layer 10 are formed on the second insulation layer 8. The third insulation layer 9 is formed, for example, such that a silicon nitride film is formed on the whole surface of the second insulation layer 8 and, thereafter, the third contact holes through which the predetermined region of the source electrode 2c is exposed are formed in the silicon nitride film by etching.

For example, a forth insulation layer 10 is formed, for example, such that an organic insulation film is formed on the whole surface of the third insulation layer 9 in which the third contact holes are formed and, thereafter, the fourth contact holes CH1 are formed in the fourth insulation layer 10 at positions corresponding to the third contact holes. The fourth contact holes CH1 are formed by etching the organic insulation film, for example. Here, a surface of the fourth insulation layer 10 is a surface on which the reflection films 11 and the first electrodes 3 are formed in steps described later and hence, the surface of the fourth insulation layer 10 is flattened or leveled.

Here, the third contact hole and the fourth contact hole may be formed simultaneously after stacking the silicon nitride film used as the third insulation layer 9 and the organic insulation film used as the fourth insulation layer 10, for example.

Next, as shown in FIG. 2C, the reflection films 11 and the auxiliary lines 6 are formed on the fourth insulation layer 10. The reflection film 11 and the auxiliary line 6 are formed, for example, such that a metal film is formed on the whole surface of the fourth insulation layer 10, a first etching resist 14 is formed on the metal film and, thereafter, the reflection films 11 and the auxiliary lines 6 are formed by etching the metal film.

Next, the first etching resist 14 is removed so as to form the first electrodes 3 and the conductive layers 12 which cover the auxiliary lines 6 as shown in FIG. 2D. The first electrode 3 and the conductive layer 12 are formed such that, for example, a transparent conductive film made of ITO, IZO or the like is formed on the whole surface of the fourth insulation layer 10, a second etching resist 15 is formed on the transparent conductive film and, thereafter, the first electrode 3 and the conductive layer 12 are formed by etching the transparent conductive film.

In this embodiment, the conductive layers 12 which cover the auxiliary lines 6 are formed together with the first electrodes 3. However, it is needless to say that the present invention is not limited to such a constitution, and only the first electrodes 3 may be formed.

Next, the second etching resist 15 is removed so as to form the bank layer 13 (fifth insulation layer) having the first opening portions CH2 and the second opening portions CH3 as shown in FIG. 2E. The bank layer 13 is formed such that, for example, an organic insulation film which covers the first electrodes 3 and the auxiliary lines 6 is formed on the whole surface of the fourth insulation layer 10 and, thereafter, the first opening portions CH2 and the second opening portions CH3 are formed. The first opening portions CH2 and the second opening portions CH3 are formed by etching, for example.

Next, as shown in FIG. 2F, the light emitting layer 4 is formed in the respective first opening portions CH2 formed in the bank layer 13. The light emitting layers 4 are made of an organic EL material, for example, and are formed by a vapor deposition method which uses a slot mask having openings at portions thereof corresponding to the first opening portions CH2. Here, the light emitting layers 4 made of an organic EL material may be formed by either one of a conventional method of forming a display panel and a forming method obtained by modifying the conventional method of forming a display panel and hence, the detailed explanation of the method of forming the light emitting layers 4 is omitted.

By forming the second electrode 5 on the whole surface of the bank layer 13 after the formation of the light emitting layers 4, the TFT substrate having the cross-sectional constitution shown in FIG. 1B can be obtained.

A manufacturing method of a display panel which uses the TFT substrate obtained by the above-mentioned manufacturing steps and a manufacturing method of an organic EL display device which uses such a display panel may be equal to the conventional manufacturing methods and hence, the detailed explanation of the manufacturing method of a display panel and the manufacturing method of an organic EL display device is omitted.

The TFT substrate of the organic EL display device according to this embodiment is manufactured by the above-mentioned steps. Here, the auxiliary lines 6 which are provided for preventing a voltage drop of the second electrode 5 are formed by etching the metal film together with the reflection films 11 positioned below the first electrodes 3. That is, the manufacturing method of the TFT substrate of this embodiment, different from the conventional manufacturing methods such as the manufacturing methods described in patent document 1 and patent document 2, does not include a step of forming only the auxiliary lines 6 or lines corresponding to the auxiliary lines 6. Accordingly, the manufacturing method of the TFT substrate of this embodiment can realize the reduction of manufacturing cost compared to the conventional manufacturing methods.

Further, in the manufacturing method of the TFT substrate of this embodiment, the auxiliary line 6 is formed by etching the metal film. Accordingly, compared to a case where the auxiliary lines 6 are formed by the vapor deposition method as in the case of the conventional manufacturing methods described in patent document 1 or patent document 2, for example, the auxiliary lines 6 can be formed with high accuracy in size and position. Due to such formation of the auxiliary lines 6 with high accuracy in size and position, in forming the first electrodes 3 and the auxiliary lines 6 on the surface of the fourth insulation layer 10, a gap between the first electrode 3 and the auxiliary line 6 (conductive layer 12) can be narrowed to an approximately 1.0 μm, for example.

That is, in the TFT substrate of this embodiment, a planar size of the first electrode 3 can be easily increased, and a planar size of the first opening portion CH2 formed in the bank layer 13 can be also increased along with the increase of the planar size of the first electrode 3. Accordingly, the organic EL display device having the TFT substrate of this embodiment can increase the numerical aperture of the pixels and hence, it is possible to enhance the brightness and the light emitting efficiency for electricity of each pixel.

As has been explained heretofore, according to the organic EL display device of this embodiment, it is possible to reduce the voltage drop of the second electrode 5 and, at the same time, it is possible to enhance the brightness and the light emitting efficiency for electricity of each pixel and hence, image quality of the organic EL display device can be enhanced.

Further, according to the method of manufacturing the TFT substrate used in the organic EL display device of this embodiment, it is possible to realize the reduction of manufacturing cost of the TFT substrate leading to the reduction of a manufacturing cost of the organic EL display device.

Although the present invention is explained specifically in conjunction with the embodiment, it is needless to say that the present invention is not limited to the above-mentioned embodiment and various modifications are conceivable without departing from the gist of the present invention.

For example, the circuit constitution of the pixel shown in FIG. 1C and the manner of operation (voltage waveform) shown in FIG. 1D respectively merely constitute one example of the circuit constitution and one example of the manner of operation of the pixel used in the organic EL display device to which the present invention is applicable. Accordingly, it is needless to say that various modifications are conceivable with respect to the circuit constitution and the manner of operation of the pixel of the organic EL display device of the present invention.

### INDUSTRIAL APPLICABILITY

The constitution of the present invention is not limited to the self-luminous display device such as the organic EL display device explained in the embodiment, and is also applicable to a planar light emitting device such as an illumination device in which light emitting elements each of which includes the first electrode 3, the light emitting layer 4, and the second electrode 5 are arranged in a matrix array, for example.

What is claimed is:

1. A display device in which pixels each of which includes a TFT element, a first electrode which is connected to the TFT element, a second electrode which faces the first electrode in an opposed manner, and a light emitting layer which is interposed between the first electrode and the second electrode are arranged on an insulation substrate in a matrix array, and the second electrode is formed of a transparent conductive material used in common by a plurality of pixels and is connected to auxiliary lines, wherein
the TFT element, the first electrode, the light emitting layer and the second electrode are stacked on the insulation substrate in this order,
the auxiliary lines are arranged between the insulation substrate and the second electrode and a bank layer which is formed of an insulation material is interposed between the auxiliary lines and the second electrode, and
the auxiliary line and the second electrode are connected with each other via a contact hole formed in the bank layer which is interposed between the auxiliary lines and the second electrode.

2. A display device according to claim 1, wherein the first electrodes and the auxiliary lines are formed on the same surface of one of insulation layer.

3. A display device according to claim 2, wherein a reflection film is arranged between the first electrode and said one of insulation layer.

4. A display device according to claim 1, wherein the bank layer is arranged on the first electrodes,
the bank layer includes opening portions through which a portion of the first electrode is exposed, and
the light emitting layer is filled in the opening portion formed in the bank layer.

5. A display device according to claim 4, wherein the pixels are arranged in a matrix array such that either one of the relationship between two pixels arranged adjacent to each other in the row direction with respect to a planar shape of the opening potion formed in the bank layer and the relationship between two pixels arranged adjacent to each other in the columnar direction with respect to a planar shape of the opening portion formed in the bank layer adopts a line symmetry using a boundary between two pixels as an axis of symmetry but does not adopt a translational symmetry.

6. A manufacturing method of a display device which forms pixels each of which includes a TFT element, a first electrode which is connected to the TFT element, a second electrode which faces the first electrode in an opposed manner and a light emitting layer which is interposed between the first electrode and the second electrode, and auxiliary lines which are connected to the second electrode on an insulation substrate, wherein
the manufacturing method comprising the steps of:
forming the TFT elements on the insulation substrate;
forming the first electrodes and the auxiliary lines;
forming an insulation layer which has first opening portions through which a portion of the first electrode is exposed and second opening portions through which a portion of the auxiliary line is exposed;
filling the light emitting layer in the first opening portion; and
forming the second electrode which is connected to the light emitting layers via the first opening portions and is connected to the auxiliary lines via the second opening portions, and
the first electrodes and the auxiliary lines are formed by etching a conductive film in the step of forming the first electrodes and the auxiliary lines.

7. A manufacturing method of a display device according to claim 6, wherein
the step for forming the first electrodes and the auxiliary lines includes steps of:
forming reflection films and the auxiliary lines by etching a metal film; and
forming the first electrodes by etching a transparent conductive film.

8. A manufacturing method of a display device according to claim 6, wherein in the step for forming the first electrodes and the auxiliary lines, a metal film and a transparent conductive film are formed continuously and, thereafter, the first electrodes, the auxiliary lines and the reflection films are formed by etching the transparent conductive film and the metal film.

9. A manufacturing method of a display device according to claim 6, wherein in the step for forming the first electrodes and the auxiliary lines, the first electrodes and the auxiliary lines are formed by etching a metal film.
